(19) United States
(12) Patent Application Publication
(10) Pub. No.: US 2010/0001347 A1
(43) Pub. Date: Jan. 7, 2010

(54) ELECTROSTATIC DISCHARGE PROTECTION DEVICE

(75) Inventor: Masayuki SUGIURA, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/495,953

(22) Filed: Jul. 1, 2009

(30) Foreign Application Priority Data
Jul. 3, 2008 (JP) 2008-174697

(51) Int. Cl. H01L 27/12

(52) U.S. Cl. 257/350; 361/56; 257/E27.112

(57) ABSTRACT

An electrostatic discharge protection device, comprising: a metal oxide semiconductor field effect transistor (MOSFET) formed on an SOI substrate, the MOSFET including a drain region connected to an input/output terminal, a source region connected to a ground terminal, a body region, a gate electrode above the body region, and a body contact region; and a trigger circuit including a diode array having at least one diode connected in series in the forward direction between the input/output terminal, and the gate electrode and the body contact region of the MOSFET, and a resistance portion connected between the ground terminal, and the gate electrode and the body contact region of the MOSFET.

### CROSS REFERENCE TO RELATED APPLICATION

This application is based upon and claims the benefit of priority from Japanese Patent Application No. 2008-174697, filed on Jul. 3, 2008, the entire contents of which are incorporated herein by reference.

### BACKGROUND

In these days, with achievement of higher integration of semiconductor integrated circuits, internal circuit elements within semiconductor devices are so miniaturized that the breakdown voltages of the internal circuit elements are lowered.

An electrostatic discharge (EDS) protection device for a metal oxide semiconductor (MOS) type device formed using a bulk silicon substrate is formed of: a gate grounded NMOS (GGNMOS) in which a gate terminal is connected to a source terminal; a gate coupled NMOS (GCNMOS) in which a gate terminal is connected to a source terminal with a resistance interposed therebetween; or a vertical parasitic bipolar transistor formed with the substrate interposed therein.

Here, a trigger voltage denotes a voltage Vt₁, at which a protection device is brought into conduction and thereby changes its occupied region from a high resistance region to a low resistance region.

Ordinarily, the trigger voltage Vt₁ is set to a voltage lower than a breakdown voltage of an internal circuit element (for example, a withstand voltage of a gate insulation film).

As described above, with the miniaturization of an internal circuit element in a semiconductor device, the breakdown voltage of the internal circuit device is lowered.

For this reason, the trigger voltage Vt₁ has to be set much lower.

To address this issue, there has been a proposal for lowering the trigger voltage Vt₁ by employing a structure that includes: an NMOS field effect transistor (NMOSFET) in which a drain is connected to an input terminal and both of a source and a substrate are connected to a ground terminal; a diode array connected in series in a forward direction between a gate of the NMOSFET and the input terminal; and a resistance connected between the gate of the NMOSFET and a ground terminal.

Having this structure, a protection device has a trigger voltage Vt₁ lower than before and thereby allows the MOSFET to operate uniformly. Thus, the protection function is improved (for example, see Japanese Patent Application Publication No. 2001-358297).

Since a capacitance element caused by the substrate is small, a device formed on an SOI (Silicon On Insulator) substrate is widely used as a high speed and small power consumption device.

However, in the case where a device is formed on an SOI substrate, an ESD protection device cannot be formed by using such vertical parasitic bipolar transistor that is to be formed with the substrate interposed therein, that is, a protection device cannot be formed by using the method for a bulk silicon substrate.

Even in the case of using the structure disclosed in Japanese Patent Application Publication No. 2001-358297, problems arise that a feature specific to the SOI structure in which electric charge is accumulated in its body region adversely affects uniform operation of the MOSFET; and that it is difficult to form a protection device achieving a high ESD protection performance.

### SUMMARY

Aspects of the invention relate to an electrostatic discharge protection device that is formed on an SOI substrate.

In one aspect of the invention, an electrostatic discharge protection device may include a metal oxide semiconductor field effect transistor (MOSFET) formed on an SOI substrate, the MOSFET including a drain region connected to an input/output terminal, a source region connected to a ground terminal, a body region, a gate electrode above the body region, and a body contact region; and a trigger circuit including a diode array having at least one diode connected in series in the forward direction between the input/output terminal, and the gate electrode and the body contact region of the MOSFET, and a resistance portion connected between the ground terminal, and the gate electrode and the body contact region of the MOSFET.

In another aspect of the invention, an electrostatic discharge protection device may include a first MOSFET formed on an SOI substrate, the first MOSFET including a drain region, a source region, a body region, a body contact region, and a gate electrode above the body region, the first MOSFET connected to an input/output terminal and a ground terminal; a first trigger circuit including a first diode array having at least one diode connected in series in the forward direction between the input/output terminal, and the gate electrode and the body contact region of the first MOSFET, and a first resistance portion connected between the ground terminal, and the gate electrode and the body contact region of the first MOSFET; a second MOSFET formed on an SOI substrate, the second MOSFET including a drain region, a source region, a body region, a body contact region, and a gate electrode above the body region, the second MOSFET connected to an input/output terminal and a power supply terminal; and a second trigger circuit including a second diode array having at least one diode connected in series in the forward direction between the power supply terminal, and the gate electrode and the body contact region of the second MOSFET, and a second resistance portion connected between the input/output terminal, and the gate electrode and the body contact region of the second MOSFET.

In another aspect of the invention, an electrostatic discharge protection device may include a metal oxide semiconductor field effect transistor (MOSFET) formed on an SOI substrate, the MOSFET including a drain region connected to an input/output terminal, a source region connected to a ground terminal, a body region, a gate electrode above the body region, and a body contact region; and a first trigger circuit including a diode array having at least one diode connected in series in the forward direction between the input/output terminal and the gate electrode of the MOSFET, and a resistance portion connected between the ground terminal and the gate electrode of the MOSFET; and a second trigger circuit including a diode array having at least one diode connected in series in the forward direction between the input/output terminal and the body contact region of the MOSFET, and a resistance portion connected between the ground terminal and the body contact region of the MOSFET.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a circuit diagram illustrating an electrostatic discharge protection device according to a first embodiment of the present invention.

FIG. 2 is a plane view schematically illustrating a MOSFET according to the first embodiment of the present invention.

FIG. 3 is a cross sectional view schematically illustrating the MOSFET according to the first embodiment of the present invention.

FIG. 4 is a cross sectional view schematically illustrating the MOSFET according to the first embodiment of the present invention.

FIG. 5 is a cross sectional view schematically illustrating the MOSFET according to the first embodiment of the present invention.

FIG. 6 is a circuit diagram illustrating an operation of the electrostatic discharge protection device according to the first embodiment of the present invention.

FIG. 7 is a circuit diagram illustrating an operation of the electrostatic discharge protection device according to the first embodiment of the present invention.

FIG. 8 is a cross sectional view schematically illustrating the MOSFET according to the first embodiment of the present invention.

FIG. 9 is a circuit diagram illustrating an operation of the electrostatic discharge protection device according to the first embodiment of the present invention.

FIG. 10 is a circuit diagram illustrating an operation of the electrostatic discharge protection device according to the first embodiment of the present invention.

FIG. 11 is a circuit diagram illustrating a modified example of the electrostatic discharge protection device according to the first embodiment of the present invention.

FIG. 12 is a circuit diagram illustrating an electrostatic discharge protection device according to a second embodiment of the present invention.

FIG. 13 is a circuit diagram illustrating an electrostatic discharge protection device according to a second embodiment of the present invention.

FIG. 14 is a circuit diagram illustrating an electrostatic discharge protection device according to another embodiment of the present invention.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

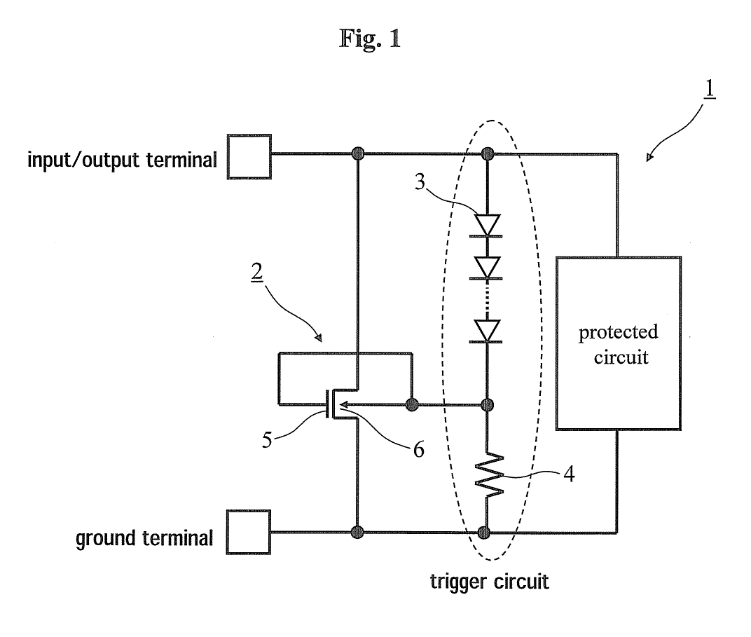

FIG. 1 is a circuit diagram illustrating an electrostatic discharge protection device according to a first embodiment of the present invention.

As shown in FIG. 1, an electrostatic discharge protection device 1 according to the first embodiment of the present invention includes: a MOSFET 2 formed on an SOI substrate; a diode array including at least one diode 3; and a resistance 4. The diode array and the resistance 4 are connected in series between a source electrode and a drain electrode of the MOSFET 2.

A gate electrode 5 and a body contact region 6 of the MOSFET 2 are connected to a connection point between the diode array and the resistance 4.

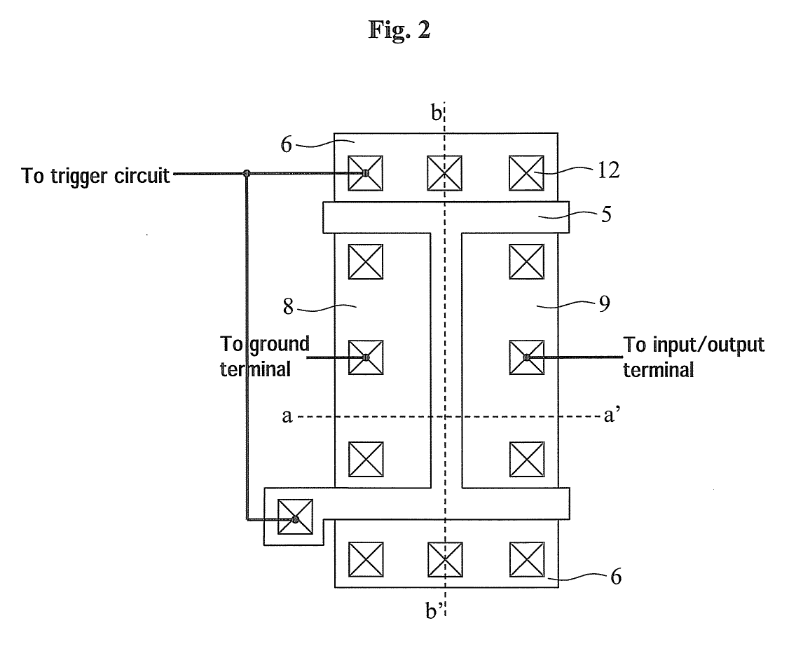

Subsequently, a structure of the MOSFET 2 is described with reference to FIGS. 2 to 4. FIG. 2 is a plane view schematically illustrating the MOSFET 2.

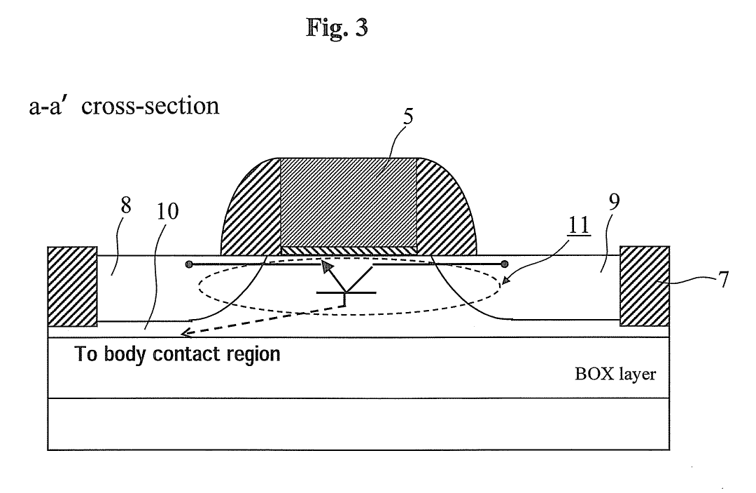

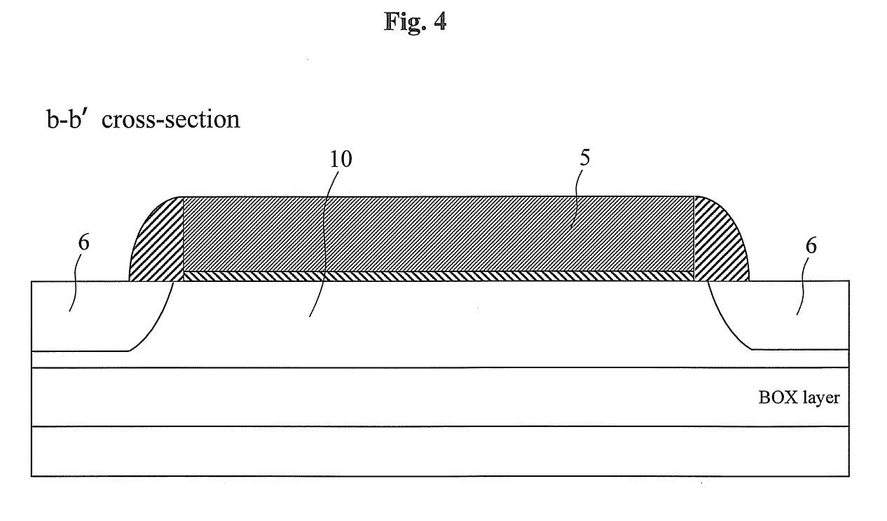

FIGS. 3 and 4 are cross sectional views each schematically illustrating a cross section of the MOSFET 2. FIG. 3 shows a cross sectional view taken along a line a-a′ in FIG. 2. FIG. 4 shows a cross sectional view taken along a line b-b′ in FIG. 2. This embodiment is described in detail for the case where the MOSFET 2 is an NMOSFET.

As shown in FIG. 3, the NMOSFET according to the first embodiment of the present invention includes device isolations 7 made of, for example, an embedded oxide film, an n⁺ type source region 8, an n⁺ type drain region 9 and a p-type body region 10.

The gate electrode 5 is disposed on the body region 10. The source region 8, the body region 10 and the drain region 9 form an npn type parasitic bipolar transistor 11.

As shown in FIG. 2 and FIG. 3, the body region 10 and the gate electrode 5 extend beyond the source region 8 and the drain region 9, and thereby form an H shape.

In addition, p⁺ type body contact regions 6 are formed at outer sides of the gate electrode 5, and are electrically connected to the body region 10 below the gate electrode 5 thereby to control the potential of the body region 10.

Further, each of the source region 8, the drain region 9 and the body contact region 6 is formed with plural contact holes 12 in each of which a plug connected to a wiring member is to be formed.

In the NMOSFET, the drain region 9 is connected to an input/output terminal, and the source region 8 is connected to a ground terminal.

This connection allows the NMOSFET portion to function as a main body of an electrostatic discharge protection circuit. In addition to the NMOSFET, another circuit in which at least one diode 3 and the resistance 4 are connected in serial between the input/output terminal and the ground terminal is formed as a trigger circuit.

The resistance 4 is set to have a resistance value of several kΩ. The diode array can be set by adjusting the number of stages of the diodes 3 according to a snapback voltage.

Both of the gate electrode 5 and the body contact region 6 are connected to the connection point of the diode array and the resistance 4 of the trigger circuit. Since the body region (p-type) 10 and the source region (n-type) 8 form a diode, the input/output line and the ground line are connected to each other in such a manner that another diode is further connected in series to the diode connected in series in an equivalent circuit model.

When a positive ESD voltage V_{ESD} is applied to the input/output terminal, the potential at the connection point between the diode array and the resistance 4 has a value obtained by dividing the ESD voltage V_{ESD} by a forward resistance of the diode array and a forward resistance of the diode formed with the body region 10 and the source region 8.

The forward resistance of the diode array depends on the number of diodes in the diode array and the size of each of the diodes.

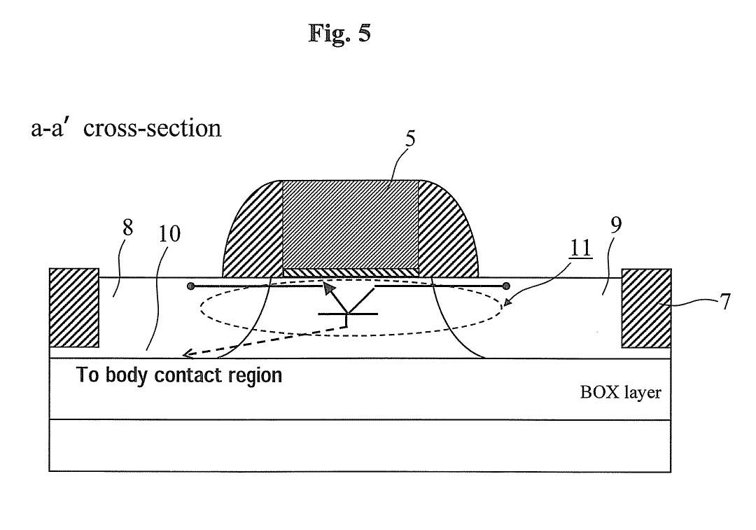

Instead, a MOSFET may have a cross-sectional structure shown in FIG. 5. In this structure, the drain region and the source region of the MOSFET are formed in such a depth as to reach a BOX layer formed as an embedded insulating film in the SOI substrate. In this case, since the drain region and the source region enclose the body region, the leak current is prevented.

This structure is more preferable because the parasitic bipolar transistor formed in the MOSFET can be driven more reliably.

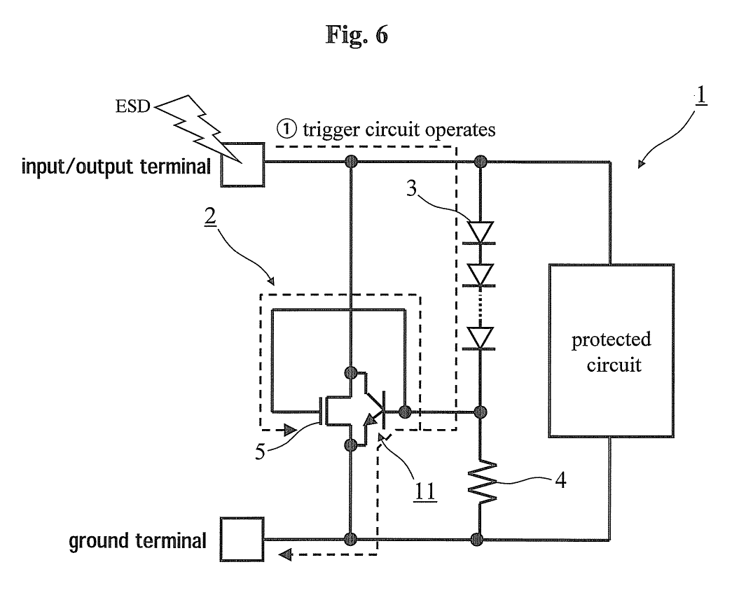

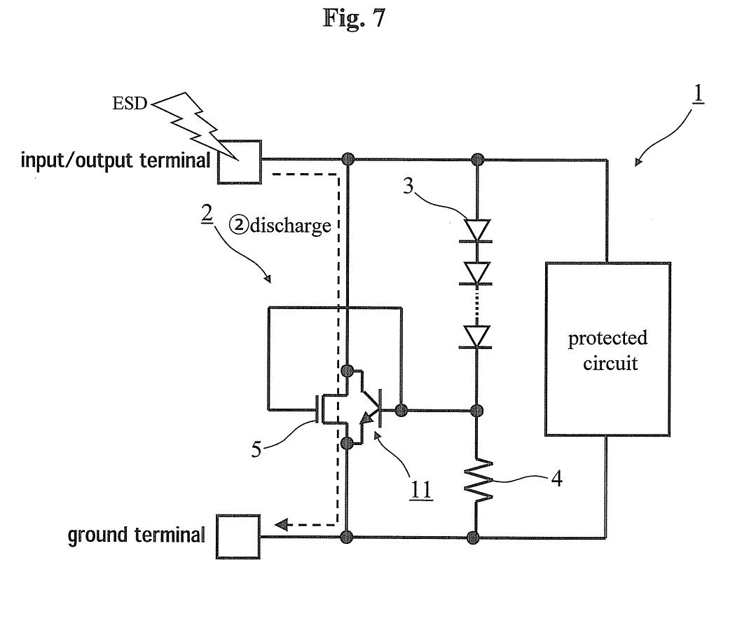

Subsequently, operations of the electrostatic discharge protection device having the structure illustrated in FIGS. 1 to 4 are described with reference to FIGS. 6 and 7. As shown in FIG. 6, in the case where an ESD voltage is applied to the input terminal, the voltage is applied to the gate electrode 5 and the body region 10 of the MOSFET 2 at a time point when the ESD voltage exceeds an ON-voltage of the diode array.

Thus, the voltage is applied to the gate electrode 5 and the body region 10 of the MOSFET 2, and at the same time, electric charge is injected into the body region 10.

When the voltage is applied to the gate electrode 5, the snapback voltage on the MOSFET 2 is lowered. Also, due to the electric charge injected in the body region, and the parasitic bipolar transistor 11 formed by the source region 8, the body region 10 and the drain region 9 of the MOSFET 2 is switched to an ON-state. Therefore, resistance between source and drain of MOSFET 2 falls rapidly, and MOSFET 2 operate as an electric discharge course (see FIG. 7).

In a device formed on a bulk silicon, the circuits included in a region other than the MOSFET portion are commonly connected to each other via the p-type substrate. In this device, when an uncontrollable voltage like an ESD voltage changes the potential of the p-type substrate, there may occur a latch-up which is unexpected in designing of the device.

Accordingly, in the conventional device structure in which the device is formed on the bulk silicon, even connecting the gate electrode 5 and the body contact region 10 to each other, it is difficult to cause the gate electrode 5 and the body contact region 10 to function as a discharge circuit.

Furthermore, since most of holes injected into the body contact region 10 from the trigger circuit flow out to the substrate, the aforementioned connection structure itself is impossible.

In the first embodiment, since the SOI substrate is used, there is no portion commonly used, like the p-type substrate, with other circuits.

Even when the gate electrode 5 and the body contact region 10 are connected to each other, a latch-up, which is unexpected in designing of the device, can be prevented from occurring. Moreover, by connecting the gate electrode 5 and the body contact region 10, an effect to improve the ESD protection performance is obtained.

The structure according to the first embodiment of the present invention is effective for two-step operation of the parasitic bipolar transistor, which is peculiar to the SOI structure. In the SOI structure, the length between the drain and the source in the body region 10 is different between a substrate inner side, and a substrate surface side that is closer to the gate electrode 5.

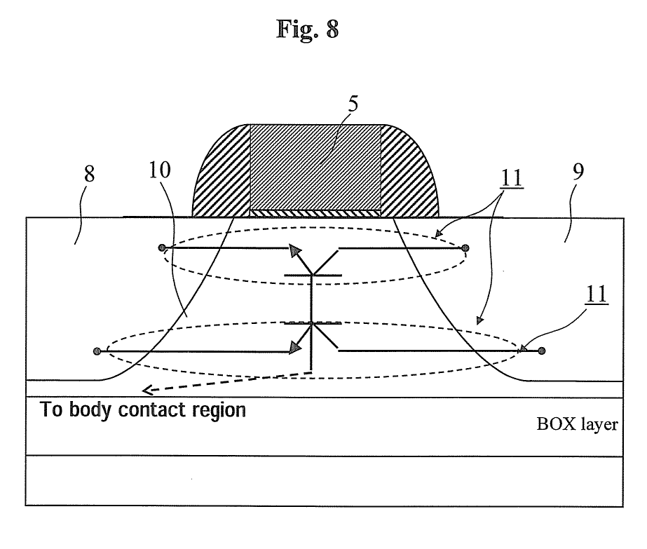

Accordingly, the current amplification ratio of the bipolar transistor is also different between the substrate surface side and the substrate inner side. For this reason, the parasitic bipolar transistor may fail to be turned ON in a full region of the transistor and consequently allow the current to flow only at substrate surface side. Thereby, the protection function may be deteriorated (see FIG. 8).

However, in the first embodiment, the trigger circuit turns ON the transistor from the outside and directly drives the bipolar transistor. Thereby, the bipolar transistor in an inner region of the substrate also functions as the discharge path.

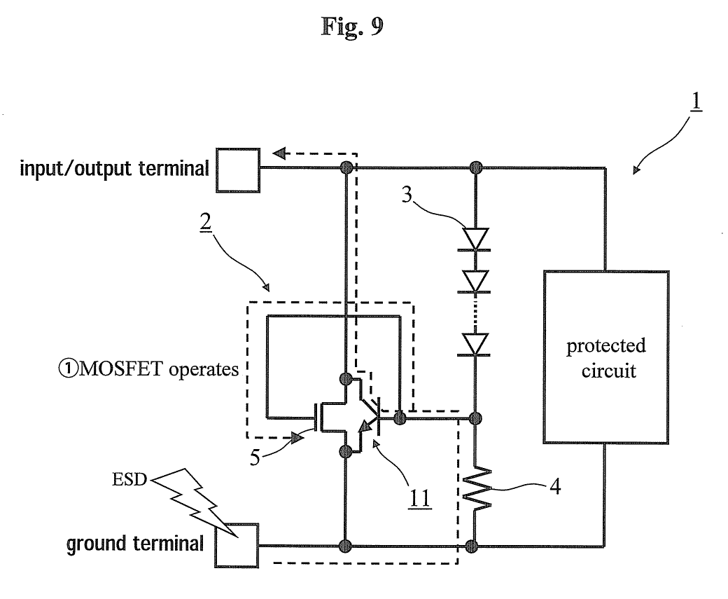

Subsequently, description is provided for the case where a negative ESD voltage is applied to the input/output terminal, i.e., a positive ESD voltage is applied to the ground terminal. Operations of the electrostatic discharge protection device in the above case are described with reference to FIG. 9.

As shown in FIG. 9, when a negative ESD voltage is applied to the input terminal, i.e., a positive ESD voltage is applied to the ground terminal, the voltage is applied to the gate electrode 5 via the resistance 4 to turn ON the MOSFET 2.

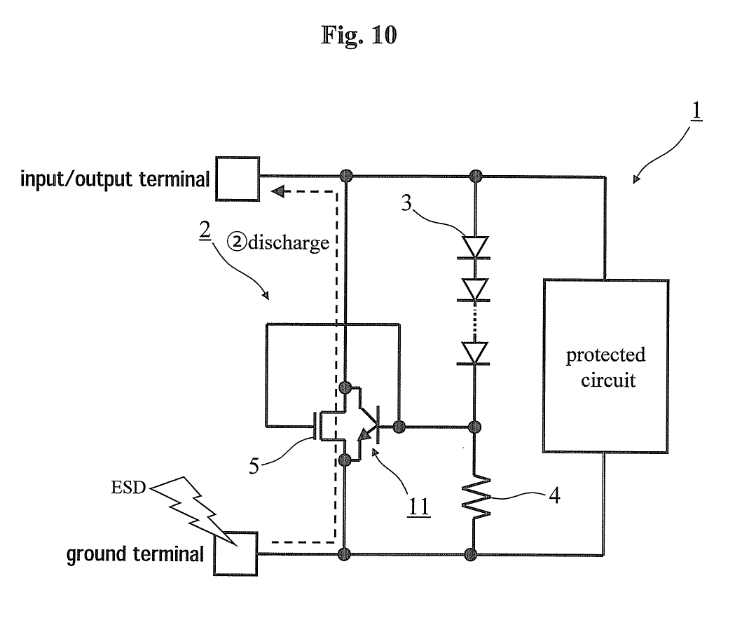

Further, since electric charge is injected into a base of the parasitic bipolar transistor 11, a discharge path via the parasitic bipolar transistor 11 is also established (FIG. 10).

In this way, the electrostatic discharge protection device according to the first embodiment is also effective for the negative ESD voltage. In summary, the electrostatic discharge protection device of the embodiment is applicable to support a two-way device.

Main parasitic capacitances formed in the circuit in this embodiment include a gate capacitance, a junction capacitance between the drain region and the body region, a diode capacitance and the like. Among these capacitances, the gate capacitance and the junction capacitance between the drain region and the body region do not operate as the parasitic capacitances in practice.

This is because the resistance 4 connected in series has such a large resistance value that the circuit as a whole has high impedance. Also, the diode capacitance has only a small amount of capacitance and affects the protection performance to a small extent only, because of the formation of the diode array in addition to the series connection of the resistance 4.

Since the first embodiment uses the SOI substrate, the substrate capacitance element can be reduced to a smaller level than in the case of using a bulk silicon substrate. Thus, the parasitic capacitance of the entire circuit in the first embodiment can be reduced to 25% or less of the parasitic capacitance of a GCNMOS protection circuit formed on a bulk silicon substrate of the same size, and can be reduced to a half or less of the parasitic capacitance of a GGNMOS protection circuit formed on an SOI substrate. The electrostatic discharge protection device in the first embodiment operates uniformly to withstand substantially the same maximum peak current as that of a bulk silicon.

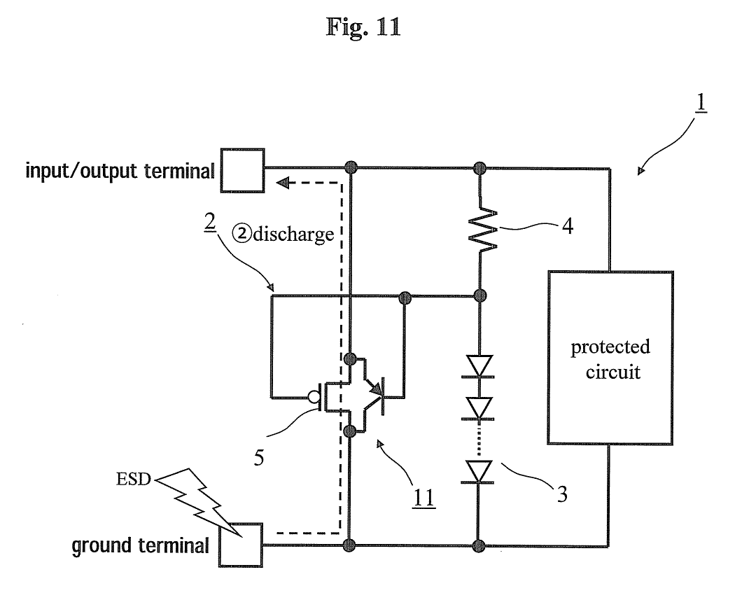

In the first embodiment, the case where the NMOSFET is used as the MOSFET 2 has been described in detail. However, in place of the NMOSFET, a PMOSFET may be used. When the PMOSFET is used, the PMOSFET can be operated as the electrostatic discharge protection device by changing the locations between the diode array and the resistance with each other, as illustrated in FIG. 11, from the locations in the case where the NMOSFET is used.

### Second Embodiment

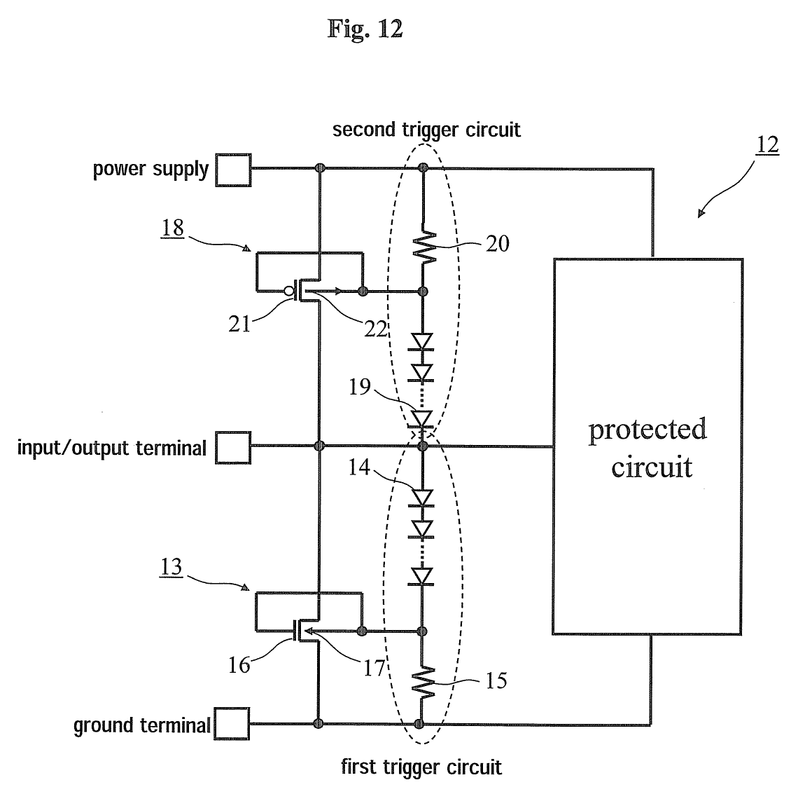

FIG. 12 is a circuit diagram illustrating an electrostatic discharge protection device according to a second embodiment of the present invention.

As shown in FIG. 12, an electrostatic discharge protection device 12 according to the second embodiment of the present invention includes: an NMOSFET 13 formed on an SOI substrate; a diode array including at least one diode 14; and a resistance 15.

The diode array and the resistance 15 are connected in series between a source electrode and a drain electrode of the NMOSFET 13. A gate electrode 16 and a body contact region 17 of the MOSFET 13 are connected to a connection point between the diode array and the resistance 15.

Sharing the input/output terminal with the protection circuit in which the NMOSFET 13 is formed, a PMOSFET 18 formed on the SOI substrate is provided.

A diode array including at least one diode 19 and a resistance 20 are connected to each other in series between a source electrode and a drain electrode of the PMOSFET 18. A gate electrode 21 and a body contact region 22 of the PMOSFET 18 are connected to a connection point of the diode array and the resistance 20.

Since the details of the respective elements are the same as those in the first embodiment, description thereof is omitted here.

FIG. 12 shows a structure in which the NMOSFET 13 is provided between the input/output terminal and the ground terminal, and the PMOSFET 18 is provided between the input/output terminal and the power source terminal.

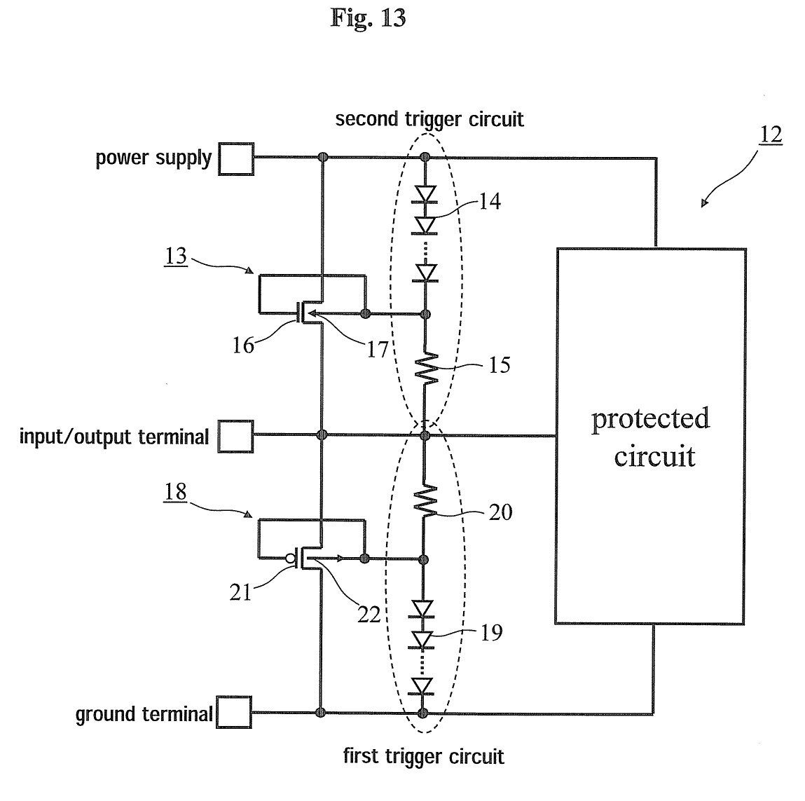

However, the locations of the NMOSFET 13 and the PMOSFET 18 may be exchanged with each other. FIG. 13 shows an example of a structure in which the locations of the NMOSFET 13 and the PMOSFET 18 are exchanged with each other. The locations of the NMOSFET and the PMOSFET are changeable according to the characteristics of a device using the protection circuits. Also, having bi-directionality, the PMOSFET may be replaced with an NMOSFET.

Since a NMOSFET can be configured to be smaller in size than a PMOSFET, an electrostatic discharge protection device configured of NMOSFETs only has an advantage of being smaller in size than a protection device configured of a PMOSFET and an NMOSFET.

Moreover, the protection device in the embodiment using both the PMOSFET and the NMOSFET is capable of performing discharge more efficiently than that in the first embodiment. The reason for such efficient discharge is specifically described below.

Although the first embodiment is applicable to a two-way device, the protection device provided with the NMOSFET only is influenced by the resistance formed in the trigger circuit when a negative ESD voltage is applied to the input/output terminal.

Therefore, the timing of establishment of the discharge path via the parasitic bipolar transistor may delay slightly.

However, in the second embodiment, the protection device provided with both of the NMOSFET and the PMOSFET is capable of performing discharge effectively when any of the positive and negative ESD voltage is applied.

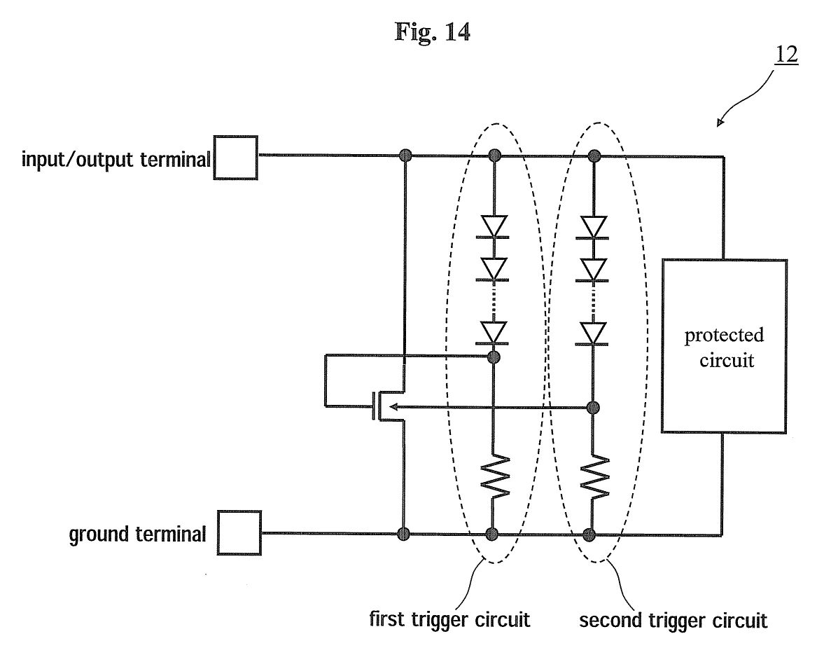

The present invention is not limited only to the above-described embodiments. Various other embodiments are possible without departing from the scope of the invention. For example, as shown in FIG. 14, an electrostatic discharge protection device 12 may includes two trigger circuits connect to MOSFET 14 formed on an SOI substrate. The trigger circuits are connected to the gate electrode and the body contact region of the MOSFET, respectively.

Moreover, the components of the respective embodiments can be arbitrarily combined without departing from the scope of the invention.

What is claimed is:

1. An electrostatic discharge protection device, comprising:
a metal oxide semiconductor field effect transistor (MOSFET) formed on an SOI substrate, the MOSFET including a drain region connected to an input/output terminal, a source region connected to a ground terminal, a body region, a gate electrode above the body region, and a body contact region; and
a trigger circuit including a diode array having at least one diode connected in series in the forward direction between the input/output terminal, and the gate electrode and the body contact region of the MOSFET, and a resistance portion connected between the ground terminal, and the gate electrode and the body contact region of the MOSFET.

2. The electrostatic discharge protection device according to claim 1, wherein the drain region and the source region of the MOSFET are formed in such a depth as to reach a BOX layer in the SOI substrate.

3. The electrostatic discharge protection device according to claim 1, wherein the body region and the gate electrode extend beyond the source region and the drain region of the MOSFET.

4. An electrostatic discharge protection device, comprising:
a first MOSFET formed on an SOI substrate, the first MOSFET including a drain region, a source region, a body region, a body contact region, and a gate electrode above the body region, the first MOSFET connected to an input/output terminal and a ground terminal;
a first trigger circuit including a first diode array having at least one diode connected in series in the forward direction between the input/output terminal, and the gate electrode and the body contact region of the first MOSFET, and a first resistance portion connected between the ground terminal, and the gate electrode and the body contact region of the first MOSFET;
a second MOSFET formed on an SOI substrate, the second MOSFET including a drain region, a source region, a body region, a body contact region, and a gate electrode above the body region, the second MOSFET connected to an input/output terminal and a power supply terminal; and
a second trigger circuit including a second diode array having at least one diode connected in series in the forward direction between the power supply terminal, and the gate electrode and the body contact region of the second MOSFET, and a second resistance portion connected between the input/output terminal, and the gate electrode and the body contact region of the second MOSFET.

5. The electrostatic discharge protection device according to claim 4, wherein the first MOSFET and the second MOSFET are NMOSFET.

6. The electrostatic discharge protection device according to claim 5, wherein the drain region of the first MOSFET connected to the input/output terminal, the source region of the first MOSFET connected to the ground terminal, the drain region of the second MOSFET connected to the power supply terminal, and the source region of the second MOSFET connected to the input/output terminal.

7. The electrostatic discharge protection device according to claim 4, wherein the drain region and source region of the first MOSFET, and the drain region and source region of the second MOSFET are respectively formed in such a depth as to reach a BOX layer in the SOI substrate.

8. The electrostatic discharge protection device according to claim 4, wherein the body region and the gate electrode of the first MOSFET respectively extend beyond the source region and the drain region of the first MOSFET, and the body region and the gate electrode of the second MOSFET respectively extend beyond the source region and the drain region of the second MOSFET.

9. An electrostatic discharge protection device, comprising:
a metal oxide semiconductor field effect transistor (MOSFET) formed on an SOI substrate, the MOSFET including a drain region connected to an input/output terminal, a source region connected to a ground terminal, a body region, a gate electrode above the body region, and a body contact region; and
a first trigger circuit including a diode array having at least one diode connected in series in the forward direction between the input/output terminal and the gate electrode of the MOSFET, and a resistance portion connected between the ground terminal and the gate electrode of the MOSFET; and
a second trigger circuit including a diode array having at least one diode connected in series in the forward direction between the input/output terminal and the body contact region of the MOSFET, and a resistance portion connected between the ground terminal and the body contact region of the MOSFET.

10. The electrostatic discharge protection device according to claim 9, wherein the drain region and the source region of the MOSFET are formed in such a depth as to reach a BOX layer in the SOI substrate.

11. The electrostatic discharge protection device according to claim 9, wherein the body region and the gate electrode extend beyond the source region and the drain region of the MOSFET.
